(19) United States
(12) Patent Application Publication
(10) Pub. No.: US 2025/0378771 A1
(43) Pub. Date: Dec. 11, 2025

(54) HARMONIC NOISE INSPECTION DEVICE FOR DISPLAY DEVICES

(71) Applicants: Samsung Display Co., LTD., Yongin-si (KR); Korea University Research and Business Foundation - Sejong Campus, Sejong-si (KR)

(72) Inventors: Kang Hyun KIM, Yongin-si (KR); Jae Woo LEE, Sejong-si (KR); So Mi LEE, Sejong-si (KR)

(21) Appl. No.: 19/065,988

(22) Filed: Feb. 27, 2025

(30) Foreign Application Priority Data
Jun. 11, 2024 (KR) 10-2024-0075512

(51) Int. Cl. G09G 3/00; G01R 31/28; G06F 3/041

(52) U.S. Cl. CPC G09G 3/006; G01R 31/2841; G06F 3/0418; G09G 2230/00

(57) ABSTRACT

In a harmonic noise inspection device for display devices, the inspection device includes an inspection control circuit configured to control image display driving of a display device during a noise inspection period, a frequency signal detector configured to detect harmonic noise signals generated from at least one of a display panel, a display circuit board, a display driver circuit, or a touch driver circuit of the display device, a signal modulation circuit configured to perform analog-digital modulation on the harmonic noise signals to generate noise signal data on the harmonic noise signals, and a signal processing circuit configured to analyze changes in amplitude of the harmonic noise signals through the noise signal data, to perform a preprocessing process of selectively removing and interpolating the noise signal data based on analysis results, and to use the preprocessed noise signal data to analyze driving characteristics of the display device.

The present application claims priority to and the benefit of Korean Patent Application No. 10-2024-0075512, filed on Jun. 11, 2024, in the Korean Intellectual Property Office, the entire disclosure of which is incorporated herein by reference.

### BACKGROUND

### 1. Field

Aspects of some embodiments of the present disclosure relate to a harmonic noise inspection device for display devices.

### 2. Description of the Related Art

As the information-oriented society evolves, consumer demands for display devices utilized with various electronic devices is ever increasing.

Such display devices may include a flat-panel display device such as liquid-crystal display devices and organic light-emitting display devices. Among such flat-panel display devices, an organic light-emitting display device includes a light-emitting element that can emit light on its own, so that each of the pixels of the display panel can emit light by themselves. Accordingly, a light-emitting display device can display images without a backlight unit that supplies light to the display panel.

The above information disclosed in this Background section is only for enhancement of understanding of the background and therefore the information discussed in this Background section does not necessarily constitute prior art.

### SUMMARY

Aspects of some embodiments of the present disclosure include a harmonic noise inspection device that performs a preprocessing process on harmonic noise signals generated from a display device and can analyze the driving characteristics of the display device using more smoothened and accurately preprocessed noise signal data.

Aspects of some embodiments of the present disclosure also include a harmonic noise inspection device a harmonic noise inspection device that can generate and use preprocessed noise signal data for easy analysis by way of comparing and analyzing noise signal data on harmonic noise signals for each frequency band with proximate noise signal data, removing and interpolating them.

It should be noted that aspects of embodiments according to the present disclosure are not limited to the above-mentioned characteristics; and other characteristics of embodiments according to the present disclosure will be apparent to those skilled in the art from the following descriptions.

According to some embodiments of the present disclosure, a harmonic noise inspection device for display devices, the inspection device comprising an inspection control circuit configured to control image display driving of a display device during a noise inspection period, a frequency signal detector configured to detect harmonic noise signals generated from at least one of a display panel, a display circuit board, a display driver circuit, or a touch driver circuit of the display device, a signal modulation circuit configured to perform analog-digital modulation on the harmonic noise signals to generate noise signal data on the harmonic noise signals, and a signal processing circuit configured to analyze changes in amplitude of the harmonic noise signals through the noise signal data, to perform a preprocessing process of selectively removing and interpolating the noise signal data based on analysis results, and to use the preprocessed noise signal data to analyze driving characteristics of the display device.

According to some embodiments of the present disclosure, a main circuit board electrically connected to a display circuit board of a display device, an inspection control circuit configured to control driving of the display device by providing image data and timing control signals to a display driver circuit of the display device through the main circuit board, a frequency signal detector configured to detect harmonic noise signals generated from at least one of a display panel, a display circuit board, a display driver circuit, or a touch driver circuit of the display device, a signal modulation circuit configured to perform analog-digital modulation on the harmonic noise signals to generate noise signal data on the harmonic noise signals, and a signal processing circuit configured to that preprocesses the noise signal data by selectively removing and interpolating data values of the noise signal data, wherein the signal processing circuit analyzes changes in amplitude of the harmonic noise signals through the noise signal data, selectively preprocesses the noise signal data based on analysis results, and uses the preprocessed noise signal data to analyze driving characteristics of the display device.

According to some embodiments of the present disclosure, a harmonic noise inspection device for display devices can analyze driving characteristics of a display device using more smoothed and accurately preprocessed noise signal data, so that the lifespan and driving characteristics of the display device can be analyzed and evaluated relatively more accurately.

In addition, according to some embodiments of the present disclosure, a harmonic noise inspection device for display devices can further improve the reliability of the analysis and evaluation of the display device by generating preprocessed noise signal data for easy analysis and using it for evaluation.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a view showing an inspection process for a harmonic noise inspection device and a display device according to some embodiments of the present disclosure.

FIG. 2 is a flowchart for illustrating a harmonic noise signal detection process and a noise signal data pre-processing process by the harmonic noise inspection device according to some embodiments.

FIG. 3 is a waveform diagram showing harmonic noise signal waveforms detected from a display device according to some embodiments.

FIG. 4 is an enlarged waveform diagram showing the harmonic noise signal waveform generated in the 100 Hz frequency band of FIG. 3.

FIG. 5 is an enlarged waveform diagram for illustrating a process of removing a harmonic noise signal and noise signal data.

FIG. 6 is a waveform diagram showing an interpolation process and results on the removed harmonic noise signal and noise signal data.

FIG. 7 is a waveform diagram showing preprocessing results of a harmonic noise signal and noise signal data according to some embodiments of the present disclosure.

### DETAILED DESCRIPTION

Aspects of some embodiments of the present disclosure will now be described more fully hereinafter with reference to the accompanying drawings, in which aspects of some embodiments of the present disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described with reference to the accompanying drawings.

The reliability of a display device on the lifespan and the period during which the display device can be used safely without inconveniences is important, not to mention the image display quality. As an inspection method for evaluating the reliability of a display device, a method of detecting noise signals generated from the display device and analyzing noise signal waveforms may be utilized. For example, by analyzing the noise signal waveforms generated from a display device, it may be possible to analyze and evaluate driving characteristics of the display device, such as changes in the driving frequency of the display device, driving signal delay time, and image display delay time. Unfortunately, because the harmonic noise signals generated in display devices have large waveform changes (amplitude and pulse width) and irregularly variable frequency bands, the reliability of inspection results may be relatively low.

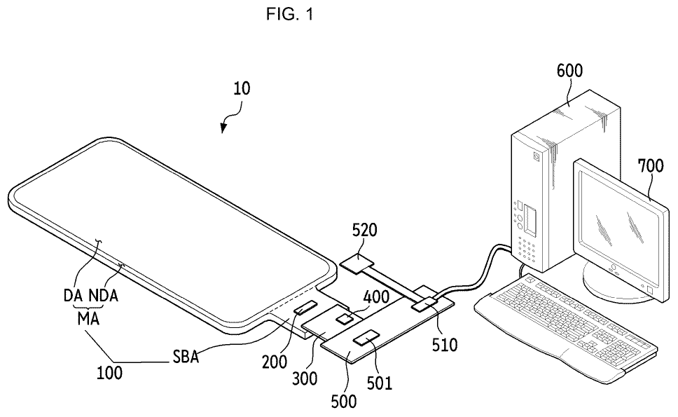

FIG. 1 is a view showing an inspection process for a harmonic noise inspection device and a display device according to some embodiments of the present disclosure.

Referring to FIG. 1, a display device 10 according to some embodiments of the present disclosure which is subject to inspection may be a portable electronic device such as a mobile phone, a smart phone, a tablet PC, a mobile communications terminal, an electronic notebook, an electronic book, a portable multimedia player (PMP), a navigation device and a ultra mobile PC (UMPC). In addition, the display device 10 according to some embodiments of the present disclosure may include a display panel of a television, a laptop computer, a monitor, an electronic billboard, or an Internet of Things (IOT) device. In addition, the display device 10 according to some embodiments of the present disclosure may be a wearable device such as a smart watch, a watch phone, a glasses-type display, and a head-mounted display (HMD) device.

According to some embodiments of the present disclosure, the display device 10 employed during inspection may be a light-emitting display device such as an organic light-emitting display device using organic light-emitting diodes, a quantum-dot light-emitting display device including quantum-dot light-emitting layer, an inorganic light-emitting display device including an inorganic semiconductor, and a micro-LED display device using micro or nano light-emitting diodes (micro LEDs or nano LEDs). In the following description, an organic light-emitting display device is described as an example of the display device 10 subject to inspection. It is, however, to be understood that embodiments according to the present disclosure are not limited thereto.

According to some embodiments of the present disclosure, the display device 10 includes a display panel 100, a display driver circuit 200, a display circuit board 300, and a touch driver circuit 400.

The display panel 100 may be formed in a rectangular plane having shorter sides in a first direction (x-axis direction) and longer sides in a second direction (y-axis direction) intersecting the first direction (x-axis direction). The display panel 100 may be formed flat, but embodiments according to the present disclosure are not limited thereto. For example, the display panel 100 includes curved portions formed at left and right ends and having a constant curvature or a varying curvature. In addition, the display panel 100 may be formed to be flexible so that it can be curved, bent, folded or rolled.

The display panel 100 includes a main area MA and a subsidiary area SBA.

The main area MA includes a display area DA where images are displayed, and a non-display area NDA around the display area DA. The display area DA includes pixels for displaying images. The subsidiary area SBA may protrude from one side of the main area MA in the second direction (y-axis direction).

The display driver circuit 200 may generate signals and voltages for driving the display panel 100. The display driver circuit 200 may be implemented as an integrated circuit (IC) and may be attached to the display device 10 by a chip on glass (COG) technique, a chip on plastic (COP) technique, or an ultrasonic bonding. It is, however, to be understood that embodiments according to the present disclosure re not limited thereto. For example, the display driver circuit 200 may be attached on the display circuit board 300 by the chip-on-film (COF) technique.

The display circuit board 300 may be attached to one end of the subsidiary area SBA of the display panel 100. The display panel 100 and the display driver circuit 200 may receive digital video data, timing signals, and driving voltages from an external graphic system or the like through the display circuit board 300. The display circuit board 300 may be a flexible printed circuit board, a printed circuit board, or a flexible film such as a chip-on film.

The touch driver circuit 400 may be located on the display circuit board 300. The touch driver circuit 400 may be implemented as an integrated circuit (IC) and may be mounted on the display circuit board 300.

Referring to FIG. 1, the harmonic noise inspection device includes a main circuit board 500, an inspection control circuit 501, a frequency signal detector 520, a signal modulation circuit 510, a signal processing circuit 600, and an inspection result display 700.

The main circuit board 500 of the harmonic noise inspection device may include a separate pad contact connector, etc., and may be electrically connected to the display circuit board 300 of the display device 10 through the pad contact connector. The main circuit board 500 may include a printed circuit board, etc., and the inspection control circuit 501 and the signal modulation circuit 510 may be mounted on the main circuit board 500.

The main circuit board 500 transmits test image data and test timing control signals output from the inspection control circuit 501 to the display circuit board 300 of the display device 10 through a pad contact connector, etc.

The inspection control circuit 501 controls the image display driving of the display device 10 during a driving characteristic inspection period through analysis of noise signals in the display device 10. In addition, the inspection control circuit 501 controls the harmonic noise signal detection operation by the frequency signal detector 520 and the analog-digital signal modulation operation by the signal modulation circuit 510.

For example, the inspection control circuit 501 provides image data and timing control signals to the display driver circuit 200 of the display device 10 through the main circuit board 500 during the driving characteristic inspection period of the display device 10, thereby controlling the image display operation by the display device 10. Then, while images are displayed on the display device 10, the inspection control circuit 501 provides a detection control signal to the frequency signal detector 520 to control the harmonic noise signal detection operation by the frequency signal detector 520 and the detection period. In addition, the inspection control circuit 501 provides an enable signal to the signal modulation circuit 510 during the period when the frequency signal detector 520 detects harmonic noise signals to control the analog-digital signal modulation operation by the signal modulation circuit 510 and the operation period.

The frequency signal detector 520 is located adjacent to at least one of the display panel 100, the display circuit board 300, the display driver circuit 200, or the touch driver circuit 400 of the display device 10.

The frequency signal detector 520 detects harmonic noise signals generated from at least one of the display panel 100, the display circuit board 300, the display driver circuit 200, or the touch driver circuit 400 of the display device 10 in response to a detection control signal from the inspection control circuit 501. The frequency signal detector 520 transmits the harmonic noise signals detected in real time to the signal modulation circuit 510.

The signal modulation circuit 510 performs analog-digital modulation on the harmonic noise signals detected and received from the frequency signal detector 520 to generate noise signal data on the harmonic noise signals. The signal modulation circuit 510 may include an analog-digital modulation circuit and a data transmission/reception module. The signal modulation circuit 510 transmits noise signal data modulated in real time to the signal processing circuit 600 through the data transmission/reception module.

The signal processing circuit 600 analyzes changes in amplitude of harmonic noise signals through noise signal data input in real time from the signal modulation circuit 510. Then, the signal processing circuit 600 performs a preprocessing process of selectively removing and interpolating the noise signal data based on the results of analyzing the changes in the amplitude of the noise signals. Accordingly, the signal processing circuit 600 may analyze the preprocessed noise signal data to extract changes in driving characteristics of the display device 10 under inspection.

For example, the signal processing circuit 600 compares the noise signal data on the harmonic noise signals with other noise signal data generated proximately in a chronological order, or compares and analyzes it with the average data of other noise signal data generated proximately in the chronological order. Then, the signal processing circuit 600 performs a preprocessing process of selectively removing and interpolating noise signal data on the harmonic noise signal based on the results of the comparison and analysis, thereby generating preprocessed noise signal data. In this manner, the signal processing circuit 600 may analyze the preprocessed noise signal data to extract changes in driving characteristics of the display device 10 under inspection.

The signal processing circuit 600 analyzes the preprocessed noise signal data, i.e., data values of the noise signal data on the harmonic noise signal after noise signal data has been removed and interpolated, and extracts changes in the driving characteristics of the display device 10 according to the frequency characteristics, the amplitude characteristics, and the pulse width characteristics of the noise signals.

The signal processing circuit 600 extracts the driving frequency, the amplitude and the pulse width of the display device 10 according to changes in the frequency characteristics, the amplitude characteristics, and the pulse width characteristics of the noise signals. In addition, the signal processing circuit 600 extracts changes in various driving characteristics of the display device 10, such as an image display speed according to changes in the driving frequency, the amplitude and the pulse width of the display device 10, and a frequency delay period, and an image display speed delay period according to the frequency delay period.

The inspection result display 700 includes a separate monitor, etc., and displays a driving characteristic analysis process and analysis results for each display device 10 by the signal processing circuit 600 on the display screen such as a monitor.

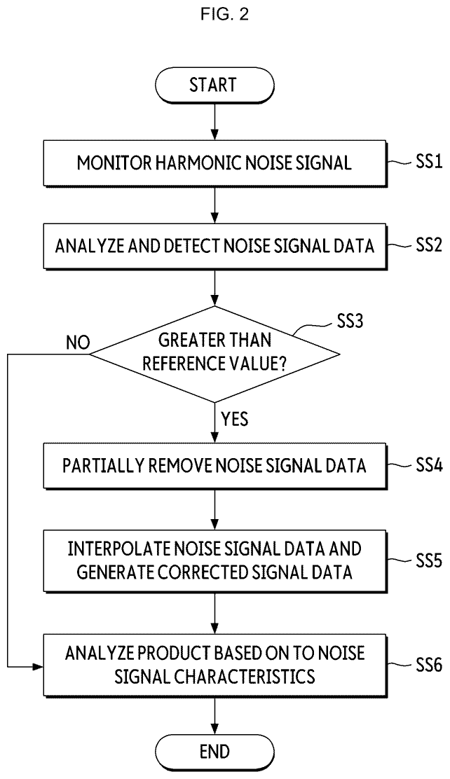

FIG. 2 is a flowchart for illustrating a harmonic noise signal detection process and a noise signal data pre-processing process by the harmonic noise inspection device according to some embodiments. Although FIG. 2 illustrates various operations in a harmonic noise signal detection process and a noise signal data pre-processing process, embodiments according to the present disclosure are not limited thereto, and according to various embodiments, a harmonic noise signal detection process and a noise signal data pre-processing process may include additional operations, or fewer operations, or the order of operations may vary, unless otherwise stated or implied, without departing from the spirit and scope of embodiments according to the present disclosure.

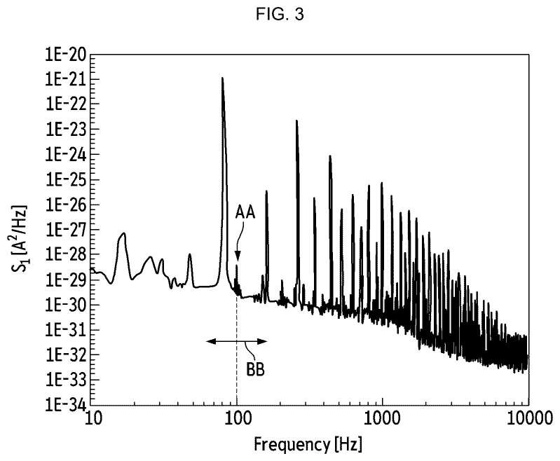

FIG. 3 is a waveform diagram showing harmonic noise signal waveforms detected from a display device according to some embodiments.

Referring to FIGS. 2 and 3, the signal processing circuit 600 monitors noise signal data values for the harmonic noise signals in a chronological order to check changes in amplitude of the harmonic noise signals.

For example, the signal processing circuit 600 extracts the noise signal data value on the harmonic noise signal detected in each of the frequency bands (e.g., the set or predetermined frequency bands). Herein, the noise signal data value may be the amplitude of the harmonic noise signal (operation SS1).

For example, the signal processing circuit 600 extracts a noise signal data value on a harmonic noise signal AA (indicated by the arrow) detected in the 100 Hz frequency band. Then, the signal processing circuit 600 may compare and analyze the noise signal data value in that frequency band (i.e., 100 Hz frequency band) with other noise signal data values generated proximately in a chronological order, and may check and analyze difference values of the compared data values.

Alternatively, the signal processing circuit 600 may compare and analyze the noise signal data value in that frequency band (i.e., 100 Hz frequency band) with average values of data values on other noise signals BB generated proximately in a chronological order (within the range indicated by the arrow), and may check and analyze difference values of the compared data values.

FIG. 4 is an enlarged waveform diagram showing the harmonic noise signal waveform generated in the 100 Hz frequency band of FIG. 3.

Referring to FIG. 4, the signal processing circuit 600 extracts a noise signal data value Pd (e.g., the amplitude of the signal) on the harmonic noise signal AA (indicated by the arrow) detected in the 100 Hz frequency band.

In addition, the signal processing circuit 600 extracts the harmonic noise signal AA (indicated by the arrow) detected in the 100 Hz frequency band and at least ten noise signal data values generated proximately in a chronological order (e.g., Pd−10 to Pd+10 values excluding the Pd value in FIG. 4). Then, the signal processing circuit 600 detects the average value on the at least ten noise signal data values Pd−10 value to Pd+10 value generated proximately in the chronological order.

Subsequently, the signal processing circuit 600 compares the noise signal data value for each frequency band (e.g., set or predetermined frequency band) with the average value of the at least 10 noise signal data values generated proximately in the chronological order and detects the difference values of the compared data values.

Subsequently, the signal processing circuit 600 compares the noise signal data value detected in the 100 Hz frequency band with the average value of the at least ten noise signal data values generated proximately to detect the difference between the compared data values (operation SS2). In this manner, by comparing the noise signal data value detected for each frequency band (e.g., set or predetermined frequency band) with the average value of the noise signal data values generated proximately, the difference values can be detected sequentially.

The signal processing circuit 600 compares a reference value (e.g., a set or predetermined reference value) (e.g., a reference amplitude) with a difference value obtained by comparing the noise signal data value detected for each frequency band (e.g., set or predetermined frequency band) with the average value of the noise signal data values generated proximately. If it is determined that the compared difference value is smaller than the reference value (e.g., set or predetermined reference value), the signal processing circuit 600 maintains the noise signal data value of that frequency band (operation SS3).

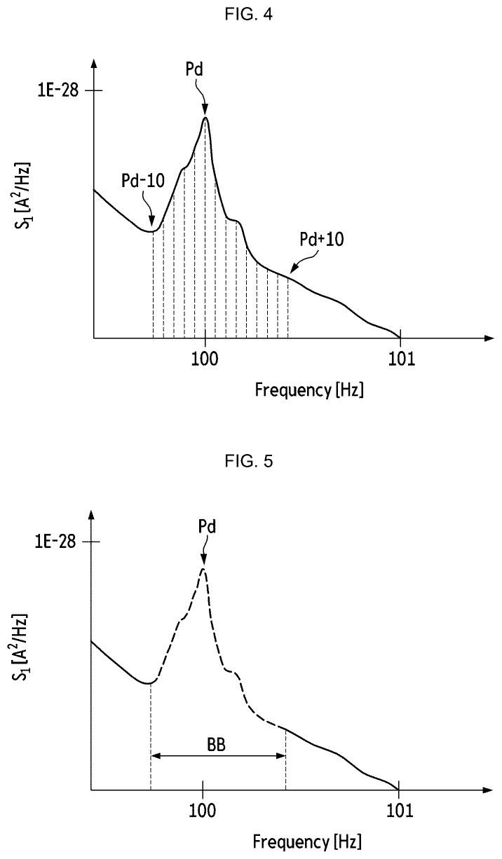

FIG. 5 is an enlarged waveform diagram for illustrating a process of removing a harmonic noise signal and noise signal data.

Referring to FIG. 5, if it is determined that the compared difference value is greater than the reference value (e.g., set or predetermined reference value), the signal processing circuit 600 removes all of the noise signal data value in that frequency band and the at least ten noise signal data values generated proximately to the noise signal data value in that frequency band in the chronological order.

For example, at least ten noise signal data values Pd−10 to Pd+10 generated proximately in the chronological order (within the range BB indicated by the arrow, with the dashed line) can be removed, along with the noise signal data value Pd (e.g., the amplitude of the signal) on the harmonic noise signal AA (indicated by the arrow) detected in the 100 Hz frequency band.

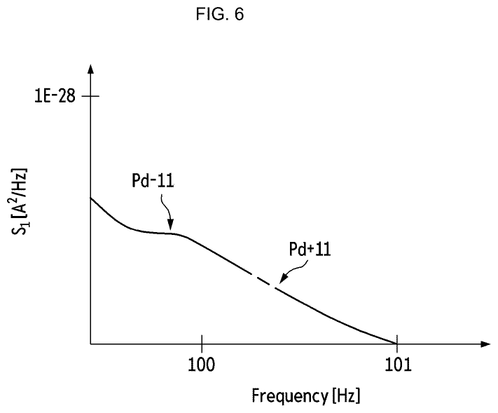

FIG. 6 is a waveform diagram showing an interpolation process and results on the removed harmonic noise signal and noise signal data.

Referring to FIG. 6, the signal processing circuit 600 sequentially interpolates the removed noise signal data values Pd−10 to Pd+10 with a value between a noise signal data value Pd−11 generated before it and a noise signal data value Pd+11 generated after it, thereby generating preprocessed noise signal data (operation SS5).

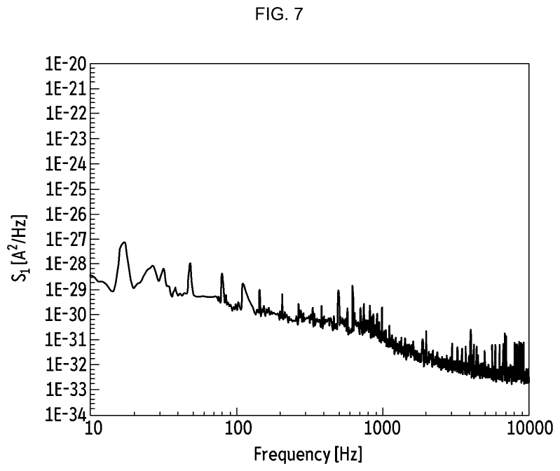

FIG. 7 is a waveform diagram showing preprocessing results of a harmonic noise signal and noise signal data according to some embodiments of the present disclosure.

Referring to FIG. 7, the signal processing circuit 600 analyzes the preprocessed noise signal data, i.e., data values of the noise signal data on the harmonic noise signal after noise signal data has been removed and interpolated, and extracts changes in the driving characteristics of the display device 10 according to the frequency characteristics, the amplitude characteristics, and the pulse width characteristics of the noise signals.

For example, the signal processing circuit 600 extracts the driving frequency, the amplitude and the pulse width of the display device 10 according to changes in the frequency characteristics, the amplitude characteristics, and the pulse width characteristics of the noise signals. In addition, the signal processing circuit 600 extracts changes in various driving characteristics of the display device 10, such as an image display speed according to changes in the driving frequency, the amplitude and the pulse width of the display device 10, and a frequency delay period, and an image display speed delay period according to the frequency delay period (operation SS6).

The inspection result display 700 includes a separate monitor, etc., and displays a driving characteristic analysis process and analysis results for each display device 10 by the signal processing circuit 600 on the display screen such as a monitor.

As described above, the harmonic noise inspection device for display devices according to some embodiments analyzes the driving characteristics of the display device 10 using more smoothed and accurately preprocessed noise signal data, so that the lifespan and driving characteristics of the display device 10 can be analyzed and evaluated more accurately.

In addition, the harmonic noise inspection device for display devices according to some embodiments may further improve the reliability of the analysis and evaluation of the display device 10 by generating preprocessed noise signal data for easy analysis and using it for evaluation.

In concluding the detailed description, those skilled in the art will appreciate that many variations and modifications can be made to the disclosed embodiments without substantially departing from the spirit and scope of embodiments according to the present disclosure. Therefore, the disclosed embodiments of the disclosure are used in a generic and descriptive sense only and not for purposes of limitation.

What is claimed is:

1. A harmonic noise inspection device for a display device, the inspection device comprising:
an inspection control circuit configured to control image display driving of the display device during a noise inspection period;
a frequency signal detector configured to detect harmonic noise signals generated from at least one of a display panel, a display circuit board, a display driver circuit, or a touch driver circuit of the display device;
a signal modulation circuit configured to perform analog-digital modulation on the harmonic noise signals to generate noise signal data on the harmonic noise signals; and
a signal processing circuit configured to analyze changes in amplitude of the harmonic noise signals through the noise signal data, to perform a preprocessing process of selectively removing and interpolating the noise signal data based on analysis results, and to use the preprocessed noise signal data to analyze driving characteristics of the display device.

2. The inspection device of claim 1, wherein the signal processing circuit is configured to compare the noise signal data on the harmonic noise signals with other noise signal data generated proximately in a chronological order, or to compare and analyze the noise signal data with average data of the other noise signal data generated proximately in a chronological order, and to generate the preprocessed noise signal data by selectively removing and interpolating the compared noise signal data based on comparison and analysis results.

3. The inspection device of claim 2, wherein the signal processing circuit analyzes data values of the preprocessed noise signal data to extract driving frequency, amplitude, and pulse width characteristics of the display device according to changes in frequency characteristics, amplitude characteristics and pulse width characteristics of the noise signals, and to extract changes in driving characteristics of the display device, comprising an image display speed according to changes in driving frequency, amplitude and pulse width of the display device, a frequency delay period, and an image display speed delay period according to the frequency delay period.

4. The inspection device of claim 1, wherein the signal processing circuit is configured to extract a noise signal data value on a harmonic noise signal detected in each of predetermined frequency bands, and to compare and analyze the noise signal data value in each of the predetermined frequency bands with other noise signal data values generated proximately in a chronological order to check and analyze a difference values of the compared data values.

5. The inspection device of claim 1, wherein the signal processing circuit is configured to extract a noise signal data value on a harmonic noise signal detected in each of predetermined frequency bands, and to compare and analyze the noise signal data value in each of the predetermined frequency bands with average values of data values on other noise signals generated proximately in a chronological order to check and analyze a difference value between the compared data values.

6. The inspection device of claim 5, wherein the signal processing circuit is configured to compare the difference value of the compared data values with a predetermined reference value, and to maintain the noise signal data value in that frequency band if the compared difference value is smaller than the predetermined reference value.

7. The inspection device of claim 5, wherein the signal processing circuit is configured to compare difference values of the compared data values with a predetermined reference value, and to remove all of the noise signal data value of that frequency band and at least ten noise signal data values generated proximately to the noise signal data value in that frequency band in a chronological order if the difference values of the compared data values are greater than the predetermined reference value.

8. The inspection device of claim 7, wherein the signal processing circuit is configured to sequentially interpolate the removed noise signal data values with a value between a noise signal data value generated before the removed noise signal data values and a noise signal data value generated after the removed noise signal data values, to generate the preprocessed noise signal data.

9. A harmonic noise inspection device for a display device, the inspection device comprising:
a main circuit board electrically connected to a display circuit board of the display device;
an inspection control circuit configured to control driving of the display device by providing image data and timing control signals to a display driver circuit of the display device through the main circuit board;
a frequency signal detector configured to detect harmonic noise signals generated from at least one of a display panel, a display circuit board, a display driver circuit, or a touch driver circuit of the display device;
a signal modulation circuit configured to perform analog-digital modulation on the harmonic noise signals to generate noise signal data on the harmonic noise signals; and
a signal processing circuit configured to preprocess the noise signal data by selectively removing and interpolating data values of the noise signal data,
wherein the signal processing circuit is configured to analyze changes in amplitude of the harmonic noise signals through the noise signal data, to selectively preprocesses the noise signal data based on analysis results, and to use the preprocessed noise signal data to analyze driving characteristics of the display device.

10. The inspection device of claim 9, wherein the signal processing circuit is configured to analyze data values of the preprocessed noise signal data to extract driving frequency, amplitude, and pulse width characteristics of the display device according to changes in frequency characteristics, amplitude characteristics, and pulse width characteristics of the noise signals, and to extract changes in driving characteristics of the display device, comprising an image display speed according to changes in driving frequency, amplitude, and pulse width of the display device, a frequency delay period, and an image display speed delay period according to the frequency delay period.

11. The inspection device of claim 9, wherein the signal processing circuit is configured to extract a noise signal data value on a harmonic noise signal detected in each of predetermined frequency bands, and to compare and analyzes the noise signal data value in each of the predetermined frequency bands with average values of data values on other noise signals generated proximately in a chronological order to check and to analyze a difference value between the compared data values.

12. The inspection device of claim 11, wherein the signal processing circuit is configured to compare the difference value of the compared data values with a predetermined reference value, and to maintain the noise signal data value in a corresponding frequency band if the compared difference value is smaller than the predetermined reference value.

13. The inspection device of claim 11, wherein the signal processing circuit is configured to compare difference values of the compared data values with a predetermined reference value, and to remove all of the noise signal data value of that frequency band and at least ten noise signal data values generated proximately to the noise signal data value in that frequency band in a chronological order if the difference values of the compared data values are greater than the predetermined reference value.

14. The inspection device of claim 13, wherein the signal processing circuit is configured to sequentially interpolate the removed noise signal data values with a value between a noise signal data value generated before the removed noise signal data values and a noise signal data value generated after the removed noise signal data values, to generate the preprocessed noise signal data.

15. The inspection device of claim 9, wherein the signal processing circuit is configured to extract a noise signal data value on a harmonic noise signal detected in each of predetermined frequency bands, and to compare and analyzes the noise signal data value in each of the predetermined frequency bands with other noise signal data values generated proximately to each other in a chronological order to check and to analyze a difference value between the compared data values.
